(19) United States
(12) Patent Application Publication
(10) Pub. No.: US 2024/0418800 A1
(43) Pub. Date: Dec. 19, 2024

(54) MAGNETIC SENSOR DEVICE

(71) Applicant: TDK CORPORATION, Tokyo (JP)

(72) Inventor: Kazuma YAMAWAKI, Tokyo (JP)

(73) Assignee: TDK CORPORATION, Tokyo (JP)

(21) Appl. No.: 18/748,563

(22) Filed: Jun. 20, 2024

(30) Foreign Application Priority Data
Jun. 19, 2023 (JP) 2023-100033

(51) Int. Cl. G01R 33/00; G01R 33/09

(52) U.S. Cl. CPC G01R 33/0005; G01R 33/098

(57) ABSTRACT

A magnetic sensor device 1 includes a support substrate 2, and a sensor substrate 10 fixed to the support substrate 2. The sensor substrate 10 includes a first surface 10B facing the support substrate 2, and a second surface 10A that is located on an opposite side to the first surface 10B and that is provided with a functional film 20 including a plurality of magnetic detection elements E, a hole portion 11 is formed in the first surface 10B, an outline O11 of the hole portion 11 includes at least one corner C1, C2, C3 . . . , and each of the plurality of magnetic detection elements E is disposed not to overlap any of the at least one corner C1, C2, C3 . . . in a plan view seen in a plane-normal direction Z from the second surface 10A toward the first surface 10B.

### CROSS-REFERENCES TO RELATED APPLICATIONS

This application claims the benefit of Japanese Priority Patent Application No. 2023-100033 filed on Jun. 19, 2023, the entire contents of which are incorporated herein by reference.

### BACKGROUND

The present disclosure relates to a magnetic sensor device.

There is a magnetic sensor device in which a sensor chip provided with a magnetic detection element on a sensor substrate is bonded to a support substrate with an adhesive. For example, Patent Publication JP-A-2023-10557 discloses a magnetic sensor device in which a first chip and a second chip each including a magnetic sensor for generating a detection signal and a support including an application specific integrated circuit (ASIC) for processing the detection signal are separately prepared, and the first chip and the second chip are bonded to the support with an adhesive. Patent Publication JP-A-2010-205893 discloses, although not being about a magnetic sensor device, that, in a semiconductor device in which a semiconductor element is mounted on a support via an adhesive layer, a recessed portion is formed on a back surface of the semiconductor element facing a support substrate.

The present disclosure has been made in view of these circumstances, and an object thereof is to provide a magnetic sensor device that can suitably fix a sensor substrate to a support substrate and has stable output characteristics.

### SUMMARY

A magnetic sensor device according to one aspect of the present disclosure includes a support substrate and a sensor substrate fixed to the support substrate. The sensor substrate includes a first surface facing the support substrate, and a second surface that is located on an opposite side to the first surface and that is provided with a functional film including a plurality of magnetic detection elements, a hole portion is formed in the first surface, an outline of the hole portion includes at least one corner, and each of the plurality of magnetic detection elements is disposed not to overlap any of at least one corner in a plan view seen in a plane-normal direction from the second surface toward the first surface. The hole portion may be a bottomed hole that is recessed from the first surface toward the second surface, or may be a through hole that penetrates from the first surface to the second surface.

According to the present disclosure, it is possible to provide a magnetic sensor device that can suitably fix a sensor substrate to a support substrate and has stable output characteristics.

### BRIEF DESCRIPTION OF DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a perspective view showing a magnetic sensor device according to one example embodiment;

FIG. 2 is a cross-sectional view schematically showing an example of an internal structure of the magnetic sensor device shown in FIG. 1;

FIGS. 3A to 3G are perspective views illustrating a manufacturing process of the magnetic sensor device shown in FIG. 1;

FIGS. 4A and 4B are diagrams showing an example of the magnetic sensor device configured as an angle sensor;

FIG. 5 is a plan view showing an example of the magnetic sensor device configured as a magnetic compass;

FIG. 6 is a diagram showing an example of the magnetic sensor device used as part of a current sensor;

FIG. 7 is a diagram showing a circuit configuration of the current sensor shown in FIG. 6;

FIG. 8 is a perspective view showing an example of the magnetic sensor device used as part of an autofocus mechanism and an optical image stabilization mechanism of a camera module;

FIG. 9 is a cross-sectional view showing an internal structure of the camera module shown in FIG. 8;

FIG. 10A is a plan view of a simulation model, in which a quadrangular hole portion is formed, seen in a plane-normal direction;

FIG. 10B is a plan view of a simulation model, in which a quadrangular hole portion with rounded (R) corners is formed, seen in the from plane-normal direction;

FIG. 10C is a plan view of a simulation model, in which a circular hole portion is formed, seen in the plane-normal direction;

FIG. 10D is a plan view of a simulation model further including a wiring layer seen in the plane-normal direction;

FIG. 10E is a plan view of a simulation model having an inclined inner surface seen in the plane-normal direction;

FIG. 11 is a cross-sectional view of the simulation model along an XY plane orthogonal to the plane-normal direction;

FIGS. 12 and 13 are diagrams showing simulated angular errors at each position shown in FIGS. 10A and 11;

FIG. 14 is a diagram showing simulated angular errors at each position shown in FIGS. 10A, 10B, and 10C;

FIG. 15 is a diagram showing angular errors obtained by simulating the model including the wiring layer shown in FIG. 10D at each position shown in FIGS. 10A, 10B, and 10C;

FIG. 16 is a diagram showing simulated angular errors at each position shown in FIG. 10E;

FIGS. 17 to 20 are plan views showing first to fourth examples in which all magnetic detection elements are disposed not to overlap outlines of the hole portions:

FIGS. 21 to 23 are plan views showing fifth to seventh examples in which a first magnetic detection element is disposed not to overlap outlines of hole portions other than corners and a second magnetic detection element is disposed not to overlap outlines of hole portions;

FIG. 24 is a plan view showing an eighth example in which magnetic detection elements are disposed inside an outline of the wiring layer; and

FIG. 25 is a cross-sectional view showing a ninth example in which magnetic detection elements are disposed not to overlap an inclined inner surface.

### DETAILED DESCRIPTION

For example, Patent Publication JP-A-2023-10557 discloses a magnetic sensor device in which a first chip and a second chip each including a magnetic sensor for generating a detection signal and a support including an application specific integrated circuit (ASIC) for processing the detection signal are separately prepared, and the first chip and the second chip are bonded to the support with an adhesive.

In such a magnetic sensor device, it is preferable to apply the adhesive so that it slightly protrudes from a bonding surface of a sensor substrate. If an amount of application of the adhesive is insufficient, there is a risk that the adhesive may be easily peeled off starting from a place at which no adhesive is applied, and an adhesion strength thereof may decrease. If the amount of application of the adhesive is excessive, there is a risk that the adhesive protruding from the sensor substrate may adhere to an electrode on a surface of the ASIC or the like, and connection reliability may decrease.

If a bottomed hole or a through hole is formed in the bonding surface of the sensor substrate, the amount of the adhesive that protrudes from a sensor chip will not change easily due to surface tension even if the amount of application changes somewhat. Since an adhesive layer becomes thicker, an adhesion strength thereof also improves. Although it is not about a magnetic sensor device, Patent Publication JP-A-2010-205893 discloses that, in a semiconductor device in which a semiconductor element is mounted on a support via an adhesive layer, a recessed portion is formed on a back surface of the semiconductor element facing a support substrate.

However, unlike the semiconductor device described in Patent Publication JP-A-2010-205893, a magnetic sensor device includes a magnetic detection element made of a magnetic material. When an external force is applied to a magnetic material, a response to a magnetic field thereof fluctuates due to the inverse magnetostriction effect. In particular, while a tunnel magnetoresistance effect element has excellent output characteristics with a large MR ratio, its output characteristics are likely to fluctuate due to an external force. In addition, when a bottomed hole or a through hole is formed in a sensor substrate, a thickness of the sensor substrate changes locally, and thus there is a risk that the thermal deformation when the sensor substrate expands or contracts due to a change in temperature may become uneven, and a thermal stress may act on the magnetic detection element.

The present disclosure has been made in view of these circumstances, and an object thereof is to provide a magnetic sensor device that can appropriately fix a sensor substrate to a support substrate and has stable output characteristics.

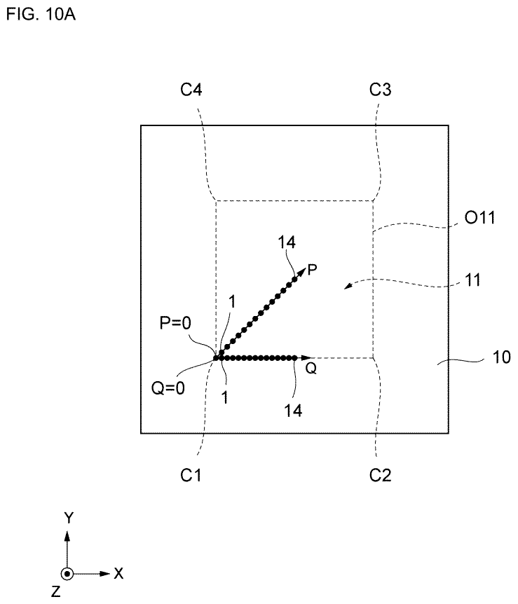

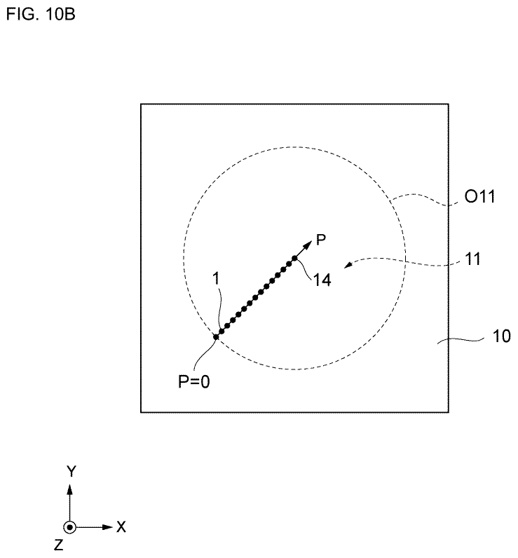

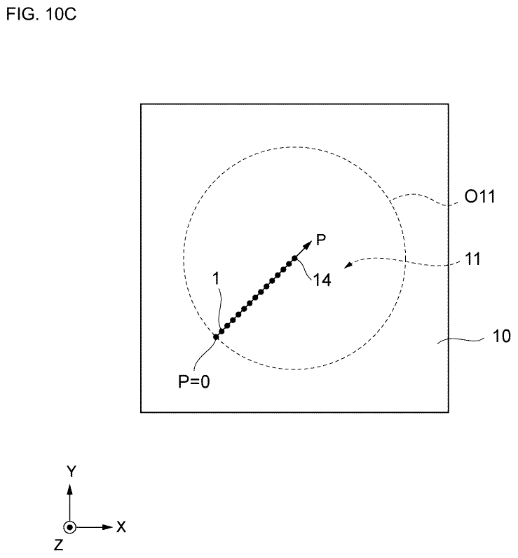

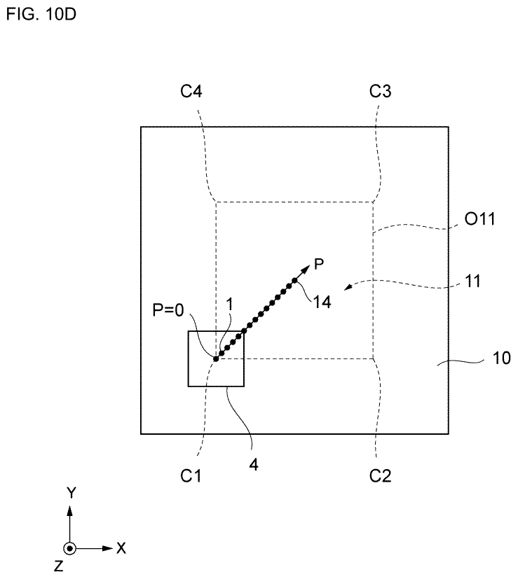

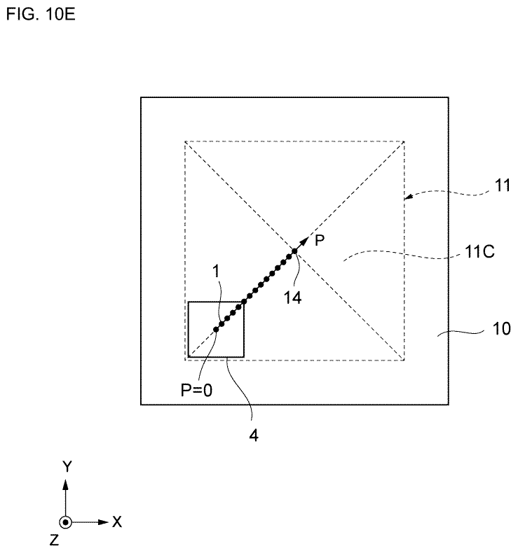

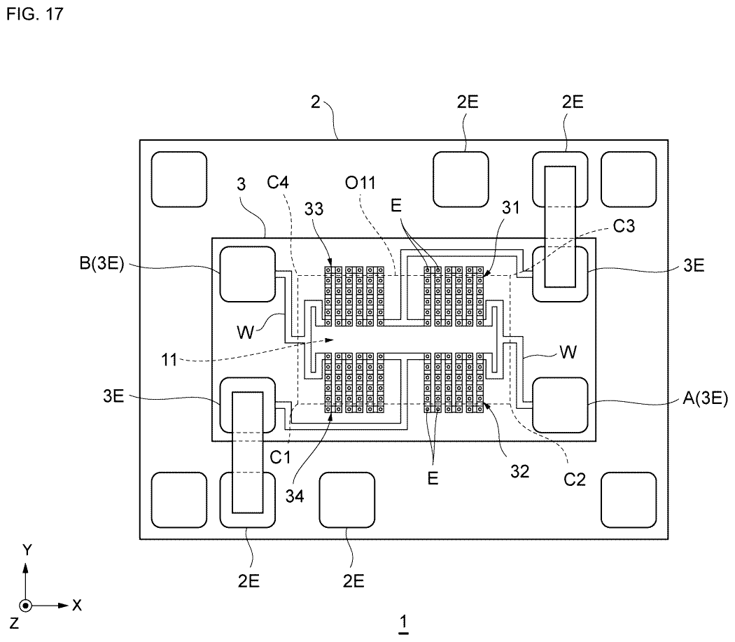

A preferred example embodiment will be described with reference to the accompanying drawings. In addition, in each figure, those with the same reference numerals have the same or similar configurations. A magnetic sensor device 1 according to one example embodiment of the present disclosure includes a hole portion 11 formed in a sensor substrate 10, and as shown in FIGS. 17 to 24, in a plan view seen in a plane-normal direction Z, each of a plurality of magnetic detection elements E is disposed not to overlap corners C1, C2, C3 . . . of an outline O11 of the hole portion 11. The outline O11 of the hole portion 11 may be a polygon such as a quadrangle including a plurality of corners C1, C2, C3 . . . or may be a circle not including the corners C1, C2, C3 . . . . The corners C1, C2, C3 . . . may be rephrased as, for example, vertices C1, C2, C3 . . . whose curvatures have the maximum value. The outline O11 of the hole portion 11 may be a combination of a teardrop-shaped vertex C1 and a curved line. For example, in circular arcs with constant curvatures each interposed between two straight lines, such as an angle R, the corners C1, C2, C3 . . . may be midpoints of the circular arcs (see FIG. 10B).

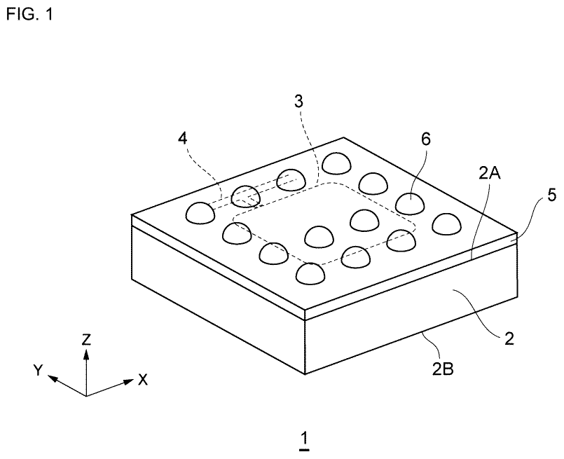

The magnetic sensor device 1 according to the example embodiment of the present disclosure includes a support substrate 2 and the sensor substrate 10 fixed to the support substrate 2 with an adhesive AD, the sensor substrate 10 has a first surface 10B facing the support substrate 2 and a second surface 10A that is located on a side opposite to the first surface 10B and provided with a functional film 20 including the plurality of magnetic detection elements E, the adhesive AD is filled in the hole portion 11 formed in a bottomed hole recessed from the first surface 10B toward the second surface 10A or a through hole penetrating from the first surface 10B to the second surface 10A, the outline O11 of the hole portion 11 includes at least one vertex C1, C2, C3 . . . whose curvature has the maximum value, and each of the plurality of magnetic detection elements E is disposed not to overlap any of the at least one vertex C1, C2, C3 . . . in a plan view seen in the plane-normal direction Z from the second surface 10A toward the first surface 10B. In the magnetic sensor device 1 according to another example embodiment of the present disclosure, the outline O11 of the hole portion 11 is a circle that does not include the vertices C1, C2, C3 . . . whose curvatures have the maximum value. The magnetic sensor device 1 of the present disclosure has the same or corresponding special technical features in that the magnetic detection elements E are disposed not to overlap the vertices C1, C2, C3 . . . whose curvatures have the maximum value regardless of whether the outline O11 of the hole portion 11 is polygonal or circular. Each configuration will be described in detail below with reference to FIGS. 1 to 25.

FIG. 1 is a perspective view showing a magnetic sensor device 1 according to one example embodiment. As illustrated, the magnetic sensor device 1 may include a support substrate 2, a sensor chip 3, a wiring layer 4, a sealing resin 5, electrodes 6, and the like. One magnetic sensor device 1 may include a plurality of sensor chips 3.

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions. As shown in FIG. 1, the support substrate 2 may be formed into a flat plate shape having an upper surface 2A and a lower surface 2B on a side opposite to the upper surface 2A. In the following description, a thickness direction of the support substrate 2 will be referred to as a plane-normal direction Z or a vertical direction Z, a direction from the lower surface 2B to the upper surface 2A will be referred to as upward, and a direction from the upper surface 2A to the lower surface 2B will be referred to as downward. The upper surface 2A may extend in parallel along an XY plane orthogonal to the plane-normal direction Z.

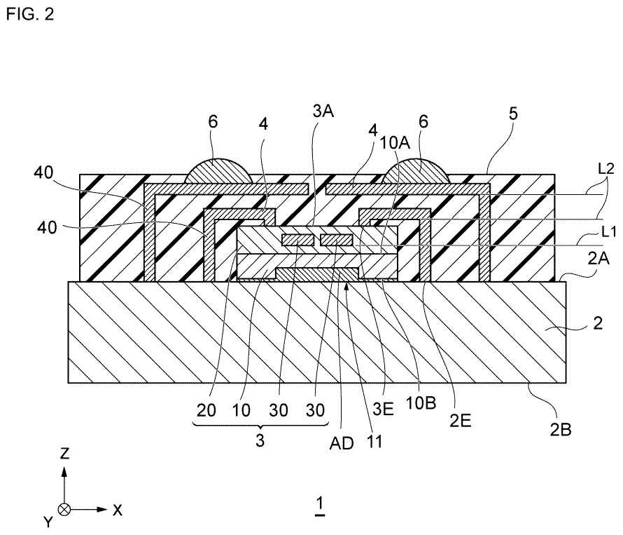

FIG. 2 is a cross-sectional view schematically showing an example of an internal structure of the magnetic sensor device 1 shown in FIG. 1. As illustrated, the support substrate 2 is an application specific integrated circuit (ASIC), and electrodes 2E electrically connected to the wiring layer 4 are provided on the upper surface 2A. The support substrate 2 is not limited to an ASIC, and may be a silicon substrate or a sapphire substrate. It may be a relay substrate (interposer) on which only wirings without integrated circuits are formed on the substrate.

The sensor chip 3 is fixed to the upper surface 2A of the support substrate 2 with the adhesive AD. As shown in FIG. 2, the sensor chip 3 includes the sensor substrate 10, at least one magnetic detection element array 30 that generates a detection signal, the functional film 20 that surrounds the magnetic detection element array 30, and the like. The functional film 20 may be an inorganic film mainly composed of silica (silicon dioxide (SiO₂)), or may be a layered film of an inorganic film mainly composed of silica and an inorganic film mainly composed of alumina (aluminum oxide (Al₂O₃)).

The sensor substrate 10 may be, for example, a silicon substrate. It may be disposed between the upper surface 2A of the support substrate 2 and the functional film 20. The sensor substrate 10 has the first surface (lower surface) 10B facing the support substrate 2 and the second surface 10A on the side opposite to the first surface 10B. The functional film 20 including the magnetic detection element array 30 is provided on the second surface 10A. The hole portion 11 is formed in the first surface 10B of the sensor substrate 10 and can be filled with the adhesive AD. The hole portion 11 may be a bottomed hole that is recessed from the first surface 10B toward the second surface 10A of the sensor substrate 10, or may be a through hole that penetrates from the first surface 10B to the second surface 10A.

Each of the magnetic detection element arrays 30 may be configured of a plurality of magnetic detection elements E (shown in FIG. 17) connected in a daisy chain and arranged in a matrix. An example of the magnetic detection element E may be a tunnel magnetoresistance effect (TMR) element. The magnetic detection element E is not limited to a TMR element, and may be a giant magnetoresistance effect (GMR) element, an anisotropic magnetoresistance effect (AMR) element, a Hall effect element, or another type of magnetic detection element. A TMR element is particularly suitable for the magnetic detection element E because it has a small junction area compared to other types of MR elements, allowing the sensor chip 3 to be made smaller, and has a large MR ratio, allowing an output of the sensor chip 3 to be increased.

The magnetic detection element array 30 may be disposed on the upper surface 2A side of the support substrate 2 and formed in a first layer L1 on the upper surface 2A side of the support substrate 2. The wiring layer 4 may be disposed on the upper surface 2A side of the support substrate 2 and formed in a second layer L2 different from the first layer L1. The second layer L2 is located at a position more distant from the support substrate 2 than the first layer L1.

The wiring layer 4 may extend in parallel along the upper surface 2A of the support substrate 2 and electrically connect the electrodes 2E of the support substrate 2 to the electrodes 3E provided on an upper surface 3A of the sensor chip 3 via a plurality of vias 40 extending in the plane-normal direction Z. The wiring layer 4 may be disposed to partially overlap the sensor substrate 10 in the plane-normal direction Z.

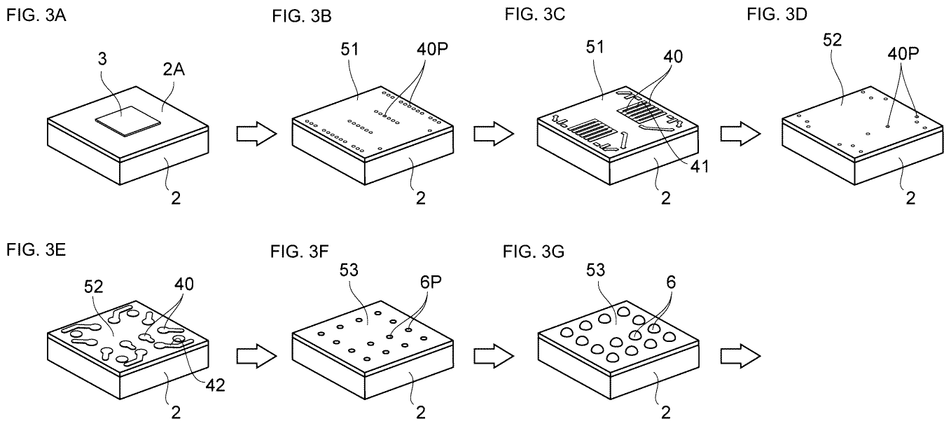

The sealing resin 5 may be disposed on the upper surface 2A side of the support substrate 2 and may cover the sensor chip 3 and the wiring layer 4. The sealing resin 5 may be configured by layering a plurality of resin layers 51, 52, 53 (shown in FIGS. 3A to 3G) extending in parallel along the upper surface 2A of the support substrate 2. The wiring layer 4 may be, for example, copper plating provided on upper surfaces of the resin layers 51 and 52. The electrodes 6 are, for example, solder balls or copper pillars, and may be electrically connected to the wiring layer 4 and exposed from the sealing resin 5.

FIGS. 3A to 3G are perspective views illustrating a manufacturing process of the magnetic sensor device 1 shown in FIG. 1. As shown in FIG. 3A, the sensor chip 3 is fixed to the upper surface 2A of the support substrate 2 with the adhesive AD (shown in FIG. 2). In this case, if an amount of application of the adhesive AD is insufficient, the adhesive is easily peeled off starting from a place at which no adhesive is applied, and if the amount of application of the adhesive AD is excessive, the adhesive protruding from the sensor chip 3 adheres to the electrodes 2E on the upper surface 2A of the support substrate 2. For that reason, for example, the adhesive AD is applied to slightly protrude from a bottom surface of the sensor chip 3.

As shown in FIG. 3B, the resin layer (first resin layer) 51 may be formed to cover the sensor chip 3 and the upper surface 2A of the support substrate 2, or through holes 40P for the vias 40 (shown in FIG. 2) may open at positions of the electrodes 2E and 3E (shown in FIGS. 10A to 10E). As shown in FIG. 3C, a seed layer may be formed by sputtering or the like, and the vias 40 and the first wiring layer 41 may be formed by plating. These processes shown in FIG. 3C may be subtractive methods or additive methods.

As shown in FIG. 3D, the resin layer (second resin layer) 52 may be formed to cover the vias 40, the first wiring layer 41, and the resin layer 51, and the through holes 40P for the vias 40 may be open. As shown in FIG. 3E, the vias 40 and the second wiring layer 42 may be formed by a process similar to that in FIG. 3C. As shown in FIG. 3F, the resin layer (third resin layer) 53 may be formed to cover the vias 40, the second wiring layer 42, and the resin layer 52, or through holes 6P for the electrodes 6 may open. As shown in FIG. 3G, the electrodes 6 may be formed by filling the through holes 6P with solder or the like. According to the procedure shown in FIGS. 3A to 3G, the magnetic sensor device 1 shown in FIG. 1 can be obtained by electrically connecting the separately prepared support substrate 2 to the sensor chip 3.

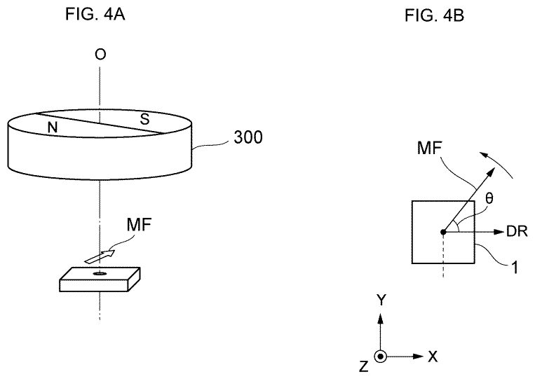

FIGS. 4A and 4B are diagrams showing an example of the magnetic sensor device 1 configured as an angle sensor that generates a detected value corresponding to an angle of a detection target. As illustrated, the magnetic sensor device 1 may be configured as an angle sensor that detects an angle of a rotatable magnet 300 with a central axis O of a cylinder as a rotation axis. In the illustrated example, the X direction, the Y direction, and the Z direction may be orthogonal to each other, and the central axis O may be parallel to the Z direction.

The magnetic sensor device 1 may detect a first component oriented in a direction parallel to the X direction of a magnetic field component MF, which is a magnetic field generated by the magnet 300 and applied to the magnetic sensor device 1, and generate a first detection signal representing an intensity of the first component, or may detect a second component oriented in a direction parallel to the Y direction of the magnetic field generated by the magnet 300 and generate a second detection signal representing an intensity of the second component. A processor (not shown) may calculate the angle θ that the magnetic field generated by the magnet 300 makes with respect to a reference direction DR by calculating an arctangent of a ratio of the first detection signal to the second detection signal.

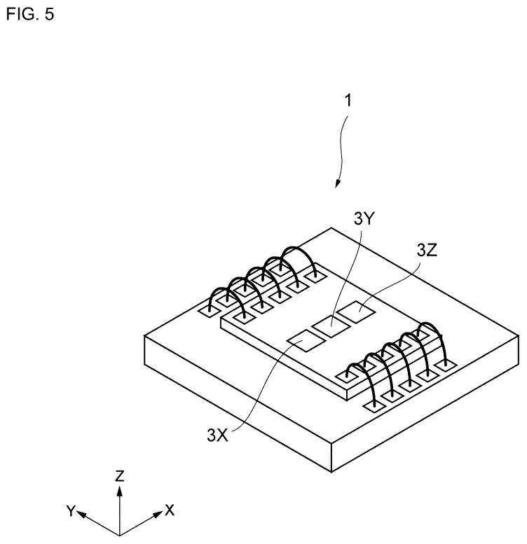

FIG. 5 is a diagram showing an example of the magnetic sensor device 1 configured as a magnetic compass that generates a detected value corresponding to an angle of geomagnetism. As shown in FIG. 5, the magnetic sensor device 1 may include three sensor chips 3 (first to third sensor chips 3X, 3Y, and 3Z), and may be configured such that the first to third sensor chips 3X, 3Y, and 3Z each detect components in three mutually orthogonal directions of an external magnetic field.

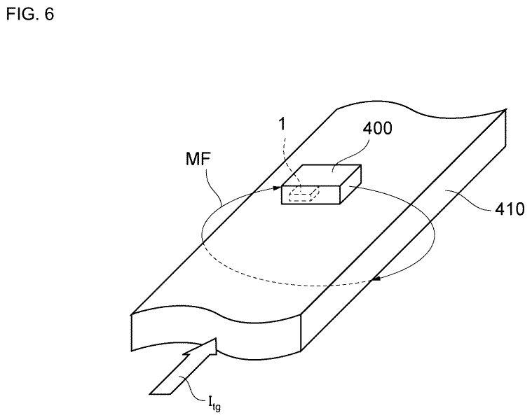

FIG. 6 is a diagram showing an example of the magnetic sensor device 1 used as part of a current sensor 400 that generates a detected value corresponding to a current value of a detection target. In the illustrated example, the current sensor 400 may be configured to detect a value of an electric current Itg flowing through a bus bar 410. A magnetic field MF is generated around the bus bar 410 by the electric current Itg. The current sensor 400 may be disposed near the bus bar 410 at a position to which the magnetic field MF is applied.

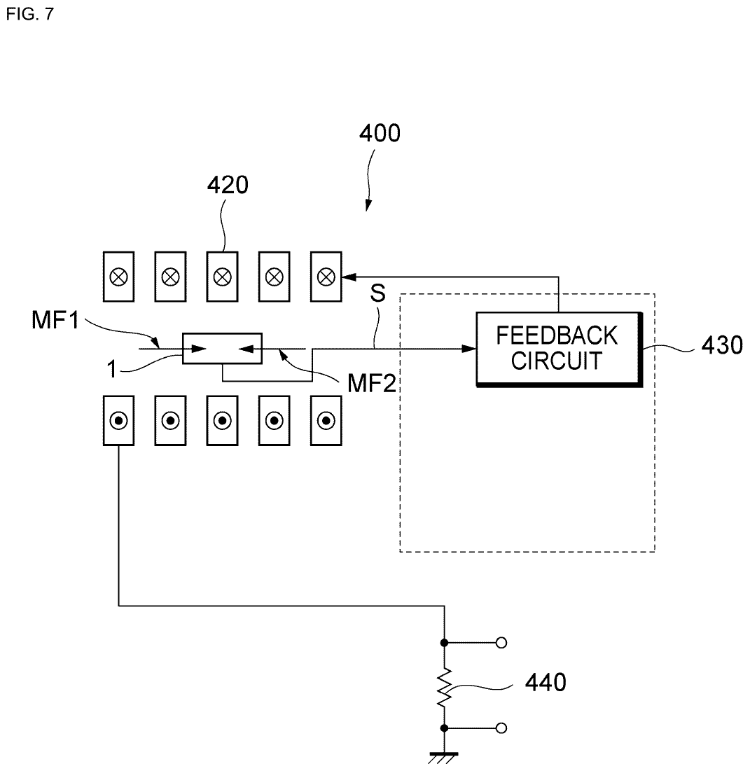

FIG. 7 is a diagram showing a circuit configuration of the current sensor 400 shown in FIG. 6. In the illustrated example, the current sensor 400 may be configured as a magnetically balanced current sensor. The current sensor 400 includes a coil 420 in addition to the magnetic sensor device 1. The coil 420 is a coil for generating a second magnetic field MF2 that cancels out a first magnetic field MF1 of the magnetic field MF. The magnetic sensor device 1 may detect a residual magnetic field between the first magnetic field MF1 and the second magnetic field MF2 and generate a magnetic field detection value S in response to an intensity of the magnetic field.

The current sensor 400 may further include a feedback circuit 430, a current detector 440, and the like. The feedback circuit 430 may cause a feedback current for generating the second magnetic field MF2 to flow through the coil 420 on the basis of the magnetic field detection value S. The current detector 440 may detect a value of the feedback current flowing through the coil 420. The current detector 440 may be, for example, a resistor inserted in a current path of the feedback current. In that case, a potential difference across the resistor may correspond to a detected value of the feedback current. Since the detected value of the feedback current is proportional to a value of the electric current Itg of the bus bar 410, the value of the electric current Itg can be detected from the detected value of the feedback current.

The magnetic sensor device 1 of the present disclosure may be installed in an electronic device such as an information device and used as a magnetic compass that detects geomagnetism, may be used as part of an autofocus mechanism or an optical image stabilization mechanism of a camera module, may be used as an angle sensor that detects an angle formed by a magnetic field generated from a magnet with respect to a reference direction, or may be used as part of a current sensor that detects a value of an electric current flowing through a bus bar. According to these aspects, the magnetic sensor device 1 can be applied to various purposes.

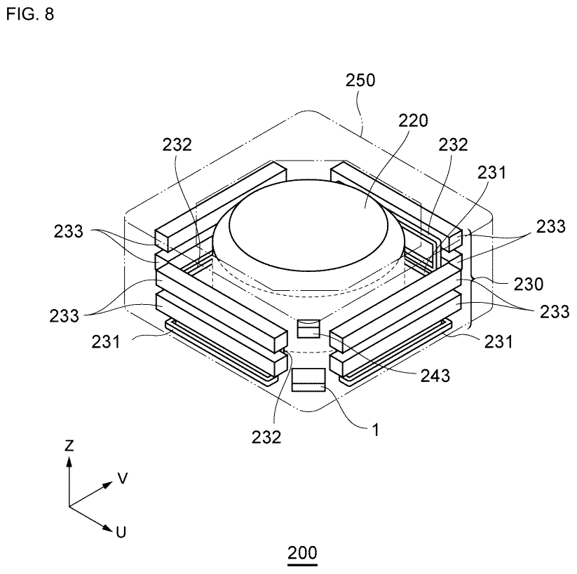

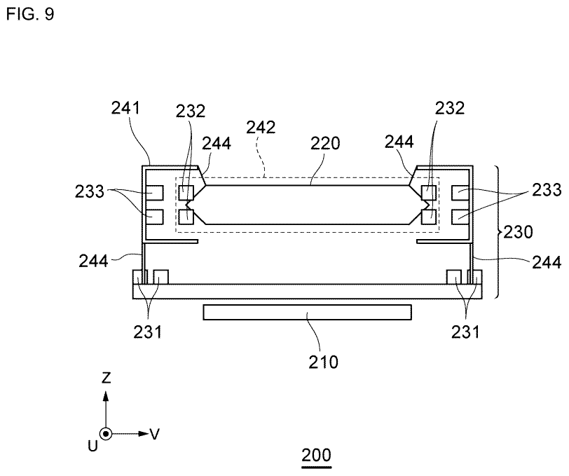

FIG. 8 is a perspective view showing an example of the magnetic sensor device 1 used as part of an autofocus mechanism and an optical image stabilization mechanism of a camera module 200. FIG. 9 is a cross-sectional view showing an internal structure of the camera module 200 shown in FIG. 8. The autofocus mechanism and the optical image stabilization mechanism of the camera module 200 may include a drive device 230 that moves a lens 220. The drive device 230 may be controlled on the basis of positional information of the lens 220 detected by a plurality of the magnetic sensor devices 1.

Specifically, the autofocus mechanism may detect a state in which a subject is in focus using an image sensor, autofocus sensor, or the like and move a lens in the Z direction relative to the image sensor. The optical image stabilization mechanism may detect camera shake using a gyro sensor or the like and move the lens in a U direction and/or a V direction with respect to the image sensor.

The camera module 200 shown in FIG. 8 may include an image sensor 210 such as CMOS, a lens 220 aligned with the image sensor 210, a first holding member 241 movable in the U direction and the V direction with respect to the image sensor 210, a second holding member 242 movable in the Z direction with respect to the first holding member 241, a plurality of elastically deformable wires 244 supporting the first holding member 241 and the second holding member 242, a drive device 230 that moves the first holding member 241 and the second holding member 242, and a housing 250 that accommodates them, and the like.

In addition to the drive device 230 and the plurality of magnetic sensor devices 1, the autofocus mechanism and the optical image stabilization mechanism of the camera module 200 may include a processor that controls the drive device 230, an autofocus sensor that detects a state in which a subject is in focus, a gyro sensor that detects camera shake, and the like. A processor, an autofocus sensor, a gyro sensor, and the like (not shown) may be disposed outside the housing.

The lens 220 may be fixed inside the second holding member 242 formed in a cylindrical shape. The second holding member 242 may be housed for each lens 220 in the first holding member 241 formed in a box shape. At least one second magnet 243 may be fixed to the second holding member 242 in order for at least one magnetic sensor device 1 to detect positional information of the second holding member 242.

The drive device 230 may include a plurality of first coils 231, a plurality of second coils 232, a plurality of first magnets 233, and the like. The plurality of first coils 231 may be fixed to the housing 250. The plurality of second coils 232 may be fixed to the second holding member 242. The plurality of first magnets 233 may be fixed to the first holding member 241. Each of the plurality of first coils 231 may face the corresponding first magnet 233. Each of the plurality of second coils 232 may face the corresponding first magnet 233.

In the case of the autofocus mechanism, when an electric current flows through any second coil 232 in response to a command from the processor, due to the interaction between the magnetic field generated from the first magnet 233 and the magnetic field generated from the second coil 232, the second holding member 242 fixed to the second coil 232 may be moved in the Z direction. At least one magnetic sensor device 1 generates a detection signal on the basis of a composite magnetic field in which a magnetic field generated from at least one second magnet 243 fixed to the second holding member 242 and a magnetic field generated from the first magnet 233 fixed to the first holding member 241 are combined together, and transmit the detection signal to the processor. The processor may detect the positional information of the lens 220 in the Z direction from the detection signal and control the drive device 230 so that the subject is in focus.

In the case of the optical image stabilization mechanism, when an electric current flows through any first coil 231 in response to a command from the processor, due to the interaction between the magnetic field generated from the first magnet 233 and the magnetic field generated from the first coil 231, the first holding member 241 fixed to the first magnet 233 may be moved in the U direction and/or the V direction. Each of the plurality of magnetic sensor devices 1 may generate a detection signal on the basis of a position of the corresponding first magnet 233 and transmit it to the processor. The processor may detect the positional information of the lens 220 in the U direction and the V direction from the detection signal and control the drive device 230 to correct camera shake.

Next, the magnetic sensor device 1 of the present disclosure will be described in detail with reference to FIGS. 10A to 25. FIG. 10A is a plan view of a simulation model, in which a hole portion 11 whose outline O11 is quadrangular is formed in the first surface 10B of the sensor substrate 10, seen in the plane-normal direction Z, and shows positions P and Q plotted on the upper surface 3A of the sensor chip 3.

As shown in FIG. 10A, plotting is made with the position immediately above the corner C1 of the hole portion 11 of 280 μm square in X axis and Y axis directions set as P=0, and the positions moved therefrom by every 10 μm in both the X axis direction and the Y axis direction respectively set as P=1, 2, 3, . . . , and 14. For example, P=14 is located at the position 140 μm apart from P=0 in both the X axis direction and the Y axis direction. Similarly, plotting is made with the position immediately above the corner C1 set as Q=0, and the positions moved therefrom by every 10 μm in the X axis direction respectively set as Q=1, 2, 3, . . . , and 14.

FIG. 10B is a plan view of a simulation model, in which a hole portion 11 whose outline O11 is a quadrangle with rounded (R) corners is formed in the first surface 10B of the sensor substrate 10, seen in the plane-normal direction Z, and shows the position P plotted on the upper surface 3A of the sensor chip 3. As shown in FIG. 10B, plotting is made with the position immediately above the corner C1 of the hole portion 11 of 340 μm square in the X axis direction and the Y axis direction, which has rounded (R) corners with a diameter of 200 μm, set as P=0 and the positions moved therefrom by every 10 μm in both the X axis direction and the Y axis direction respectively set as P=1, 2, 3, . . . , and 14.

FIG. 10C is a plan view of a simulation model, in which a circular hole portion 11 is formed in the first surface 10B of the sensor substrate 10, seen in the plane-normal direction Z, and shows the position P plotted on the upper surface 3A of the sensor chip 3. As shown in FIG. 10C, plotting is made with the position immediately above the outline O11 of the circular hole portion 11 with a diameter of 400 μm set as P=0 and the positions moved therefrom by every 10 μm in both the X axis direction and the Y axis direction respectively set as P=1, 2, 3, . . . , and 14.

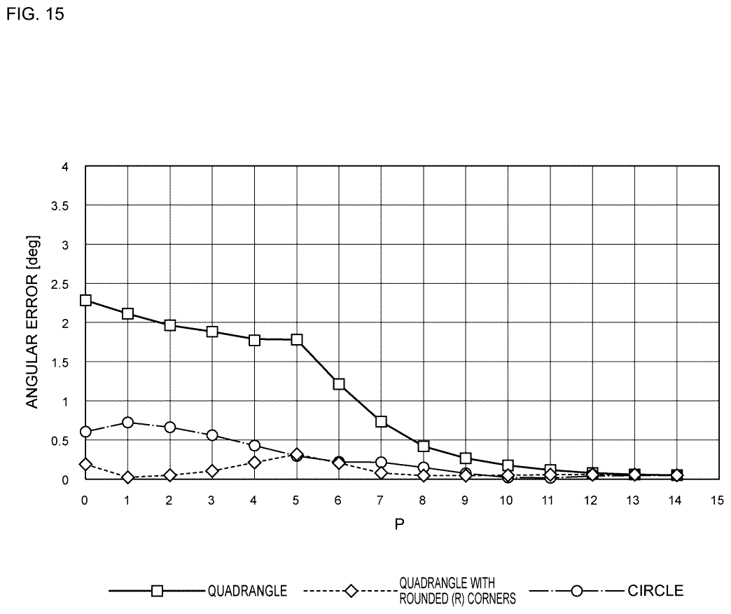

FIG. 10D is a plan view of a simulation model, in which the model shown in FIG. 10A further includes a wiring layer 4 of 100 μm square in the X axis direction and the Y axis direction, seen in the plane-normal direction Z. The wiring layer 4 is disposed so that its center is located at the position of P=0. In the simulation results of FIG. 15, which will be described later, similarly to FIG. 10D, the models shown in FIGS. 10B and 10C also include the wiring layer 4 of 100 μm square in the X axis direction and the Y axis direction, which is disposed so that the position of P=0 becomes its center.

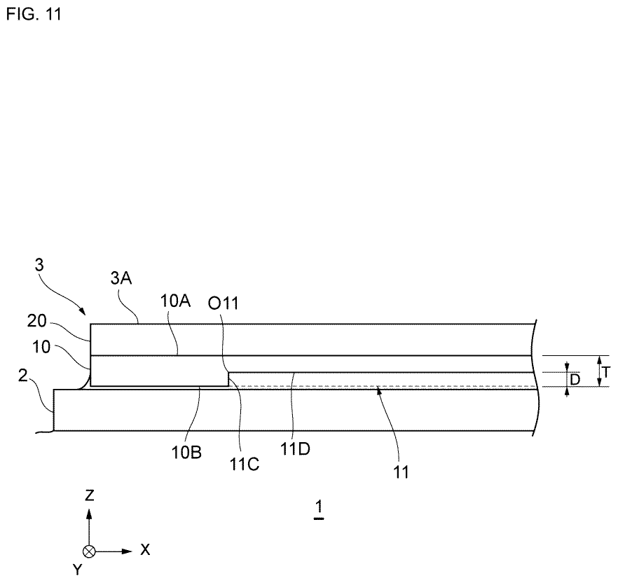

FIG. 10E is a plan view of a simulation model having an inner surface 11C inclined with respect to the plane-normal direction Z seen in the plane-normal direction Z, and shows the position P plotted on the upper surface 3A of the sensor chip 3. As shown in FIG. 10E, the simulation model is a hole portion 11 of 400 μm square in the X axis direction and the Y axis direction, and a depth D of the deepest center thereof shown in FIG. 11, which will be described later, is 15 μm, there is no bottom surface 10D, and instead, an inner surface 11C thereof is formed as an inclined surface or in a step shape. In this simulation model, the wiring layer 4 shown in FIG. 10D is added to overlap the hole portion 11, and plotting is made with the position immediately below the center of the wiring layer 4 set as P=0 and the positions moved therefrom by every 10 μm in both the X axis direction and the Y axis direction set as P=1, 2, 3, . . . and 14.

FIG. 11 is a cross-sectional view of the simulation model along an XY plane orthogonal to the plane-normal direction Z. In addition, the outline O11 of the hole portion 11 is an outline of a bottom surface 11D of the hole portion 11 and is defined by a boundary between the bottom surface 11D and the inner surface 11C. A rounded (R) corner may be provided at the boundary between the bottom surface 11D and the inner surface 11C. In that case, if the bottom surface 11D is flat and the depth D from the first surface 10B to the bottom surface 11D is substantially constant, the position at which the depth D starts to gradually decrease is the boundary between the bottom surface 11D and the inner surface 11C.

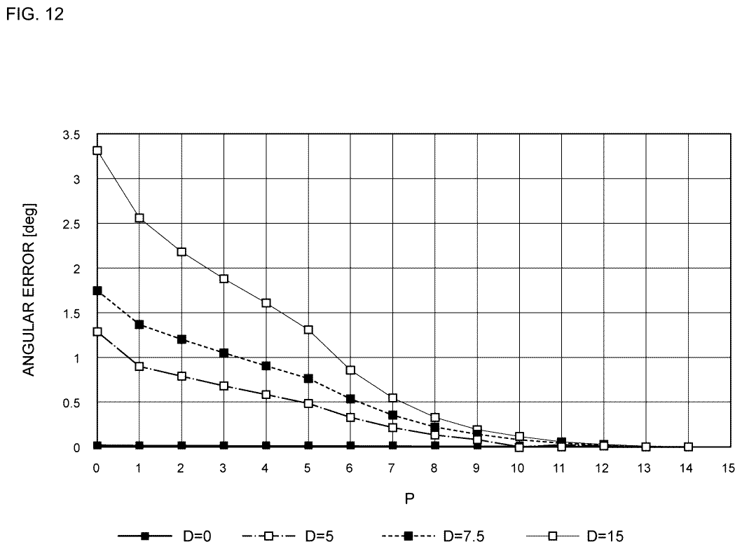

In the simulation results of FIGS. 12 to 16, which will be described later, a thickness T of the sensor substrate 10 from the first surface 10B to the second surface 10A is 15 μm, and a film thickness of the functional film 20 is also 15 μm. In the simulation results of FIG. 15, which will be described later, the distance from the upper surface 3A of the sensor chip 3 to a lower surface of the wiring layer 4 is 5 μm.

FIG. 12 is a diagram showing simulated angular errors at each depth D shown in FIG. 11 at the position P shown in FIG. 10A, and the simulation results of the angular errors are plotted on the vertical axis in a case in which the position P shown in FIG. 10A is changed to 15 patterns from 0 to 14, the depth D from the first surface 10B of the sensor substrate 10 to the bottom surface 11D of the hole portion 11 shown in FIG. 11 is changed to 4 patterns of 0 μm, 5 μm, 7.5 μm, and 15 μm, and a predetermined stress value is applied to the magnetic sensor device 1.

When the depth D is less than 15 μm, the hole portion 11 is formed as a bottomed hole that is recessed from the first surface 10B toward the second surface 10A of the sensor substrate 10. When the depth D is 15 μm, the hole portion 11 is formed as a through hole that penetrates from the first surface to the second surface. Even if the hole portion 11 is a through hole, the magnetic detection elements E are fixed by the functional film 20 that surrounds the magnetic detection elements E.

As shown in FIG. 12, the angular error increases at a position closer to P=0. When the magnetic detection elements E are located immediately above the corner C1, they are likely to be influenced by a thermal stress from the sensor substrate 10. In an in-plane direction perpendicular to the plane-normal direction Z, each of the magnetic detection elements E is disposed at intervals of 10 μm or more from each of the corners C1 to C4, for example. Further, the angular error increases at a position at which the depth D of the hole portion 11 is larger. The depth D of the hole portion 11 is, for example, less than or equal to half of the thickness T of the sensor substrate 10, which is 30 μm.

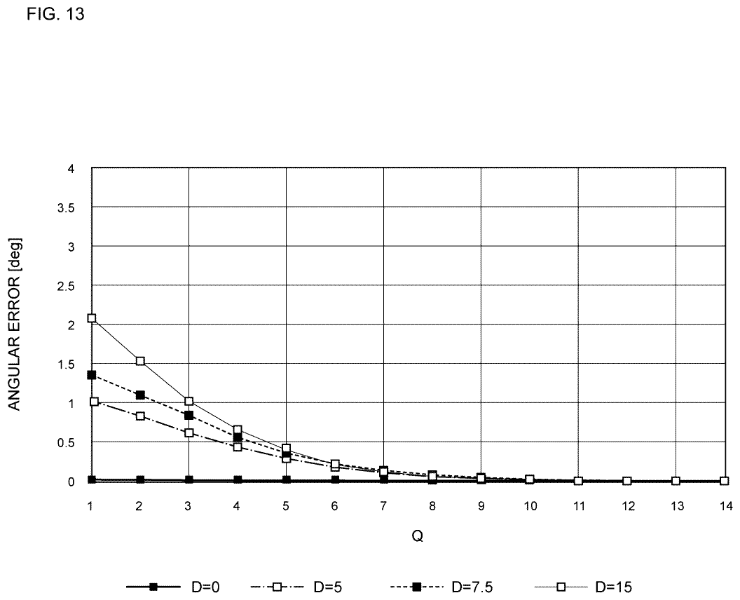

FIG. 13 is a diagram showing simulated angular errors at each depth D shown in FIG. 11 at the position Q shown in FIG. 10A, and the simulation results of the angular errors are plotted on the vertical axis in a case in which the position Q shown in FIG. 10A is changed to 14 patterns from 1 to 14 on the horizontal axis, the depth D of the hole portion 11 shown in FIG. 11 is changed to 4 patterns of 0 μm, 5 μm, 7.5 μm, and 15 μm, and a predetermined stress value is applied to the magnetic sensor device 1.

As shown in FIG. 13, the angular error increases at a position closer to Q=0 (same value as the plot of P=0 shown in FIG. 12). When the magnetic detection elements E are located immediately above the corner C1, they are likely to be influenced by the thermal stress from the sensor substrate 10. Regardless of whether the position is P moving away from the outline O11 of the hole portion 11 or Q moving on the outline O11 of the hole portion 11, the angular error tends to increase at a position closer to the corner C1.

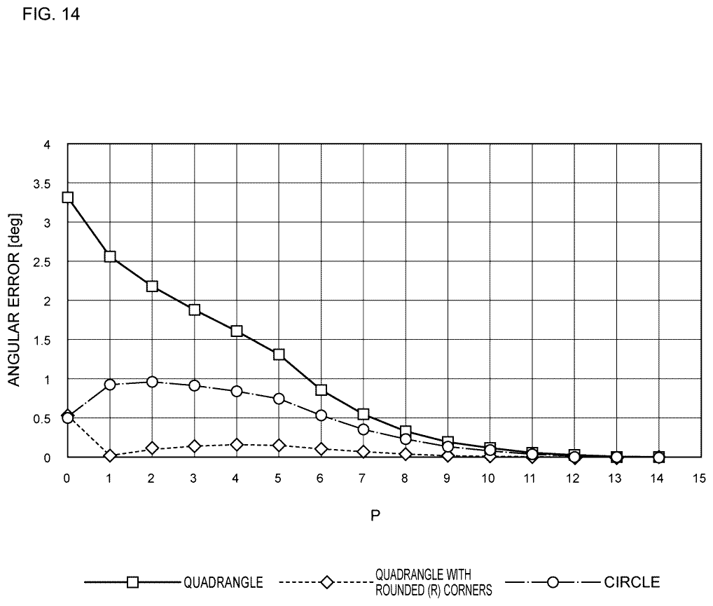

FIG. 14 shows the simulated angular errors in a case in which the depth D of the hole portion 11 is fixed at 15 μm, the positions P shown in FIGS. 10A, 10B, and 10C are changed to 15 patterns from 0 to 14, and a predetermined stress value is applied to the magnetic sensor device 1.

As shown in FIG. 14, the angular error tends to increase in the order of the model in which the outline O11 of the hole portion 11 is a quadrangle with rounded (R) corners, the model in which the outline O11 of the hole portion 11 is a circle, and the model in which the outline O11 of the hole portion 11 is a quadrangle. In either model, the angular error increases at the position closer to P=0. When the magnetic detection elements E are located immediately above the corner C1, they are likely to be influenced by the thermal stress from the sensor substrate 10.

FIG. 15 shows the simulated angular errors in a case in which the depth D of the hole portion 11 is fixed at 15 μm, the wiring layer 4 shown in FIG. 10D is added, the positions P shown in FIGS. 10A, 10B, and 10C are changed to 15 patterns from 0 to 14, and a predetermined stress value is applied to the magnetic sensor device 1.

When the simulation results of FIGS. 14 and 15 are compared with each other, regardless of whether the outline O11 of the hole portion 11 is a quadrangle, a rounded (R) quadrangle, or a circle, the model with the wiring layer 4 tends to have a smaller angular error than the model without the wiring layer 4 at the positions of P=0 to 3 at the inside of the outline O4 of the wiring layer 4. That is, it can be expected that they will be less likely to be influenced by the thermal stress of the sensor substrate 10. However, in the quadrangular model, the model with the wiring layer 4 has a larger angular error than the model without the wiring layer 4 at the positions of P=4 to 6 near the outline O4 of the wiring layer 4.

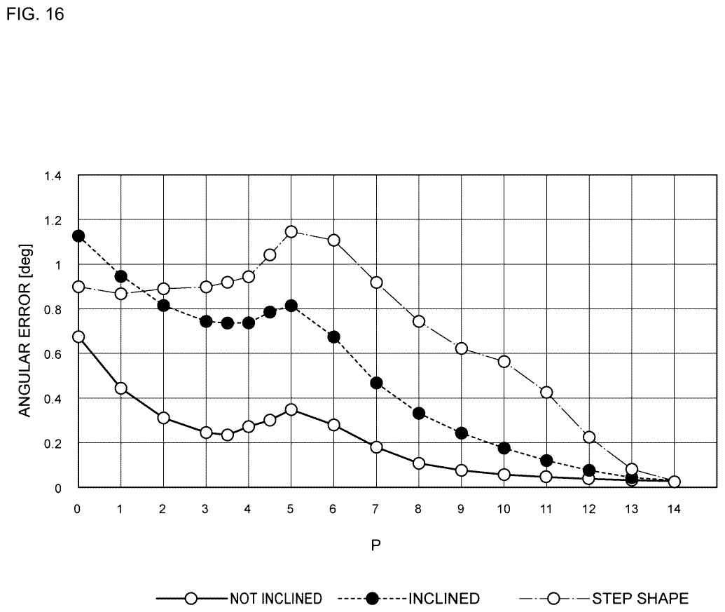

FIG. 16 shows the simulated angular errors in a case in which P shown in FIG. 10E is changed to 15 patterns from 0 to 14, and a predetermined stress value is applied to the magnetic sensor device 1. When the simulation results of FIGS. 15 and 16 are compared with each other, in both the model in which the inner surface 11C is inclined with respect to the plane-normal direction Z and the model in which the inner surface 11C is formed in a step shape, the angular errors are larger than the angular error of the model in which the inner surface 11C is not inclined. That is, there is a tendency that they are likely to be influenced by the thermal stress from the sensor substrate 10.

Appropriate examples of the present disclosure will be described with reference to FIGS. 17 to 25. As described above with reference to FIGS. 12 to 15, the angular error increases at positions closer to the corners C1 to C4. When the magnetic detection elements E are located immediately above the corners C1 to C4, they are likely to be influenced by the thermal stress from the sensor substrate 10. FIGS. 17 to 20 are plan views showing first to fourth examples in which all the magnetic detection elements are disposed not to overlap the outline of the hole portion. All the magnetic detection elements E are disposed not to overlap the outline O11 of the hole portion 11. In the first to fourth examples, since each of the plurality of magnetic detection elements E does not overlap any of the corners C1 to C4 of the outline O11 of the hole portion 11 in a plan view, the magnetic detection elements E are less likely to be influenced by the thermal stress from the sensor substrate 10.

In the first example shown in FIG. 17, in a plan view, some of the plurality of magnetic detection elements E are disposed at the inside of the outline O11 of the hole portion 11, and the rest of the plurality of magnetic detection elements E are disposed at the outside of the outline O11 of the hole portion 11. In other words, in the first example shown in FIG. 17, the magnetic detection elements are disposed across the inside and the outside of the outline O11.

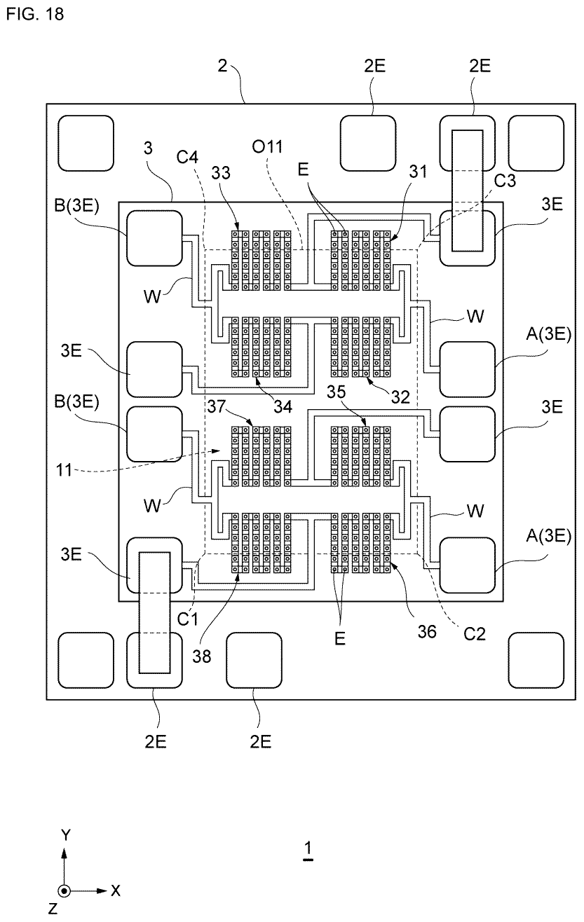

As in the second example shown in FIG. 18, the hole portion 11 may be disposed across a plurality of bridge circuits. In the examples shown in FIGS. 17 to 24, the magnetic sensor device 1 includes first to fourth magnetic detection element arrays 31, 32, 33, and 34, and a first bridge circuit is configured by two parallel circuits. In the second example shown in FIG. 18, the magnetic sensor device 1 further includes fifth to eighth magnetic detection element arrays 35, 36, 37, and 38, and a second bridge circuit is configured by two parallel circuits.

The first magnetic detection element array 31 and the second magnetic detection element array 32 are connected in series to each other with an output port A interposed therebetween to form one parallel circuit of the first bridge circuit, and the third magnetic detection element array 33 and the fourth magnetic detection element array 34 may be connected in series to each other with an output port B interposed therebetween to form the other parallel circuit of the first bridge circuit. Similarly, the fifth magnetic detection element array 35 and the sixth magnetic detection element array 36 may be connected in series to each other with the output port A interposed therebetween to form one parallel circuit of the second bridge circuit, and the seventh magnetic detection element array 37 and the eighth magnetic detection element array 38 may be connected in series to each other with the output port B interposed therebetween to form the other parallel circuit of the second bridge circuit. The output ports A and B may be connected to a galvanometer or the like. In the second example shown in FIG. 18, similarly to the first example, the magnetic detection elements are disposed across the inside and the outside of the outline O11.

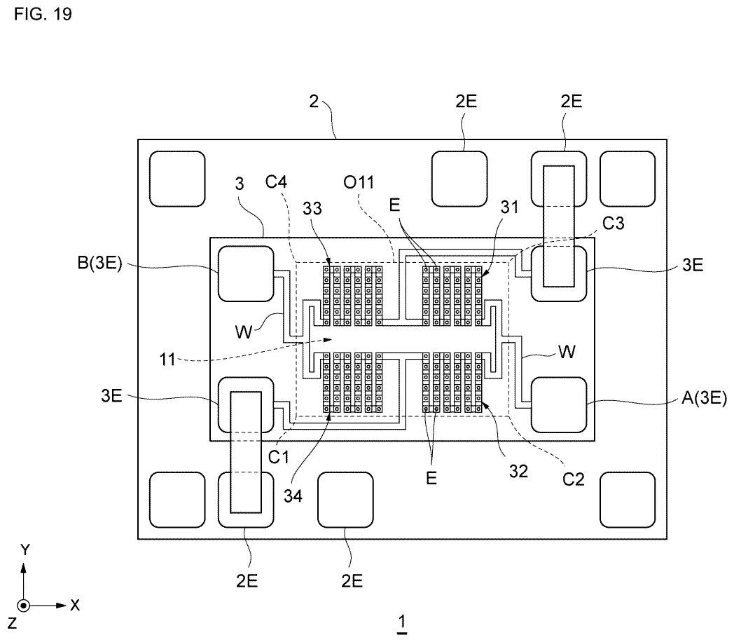

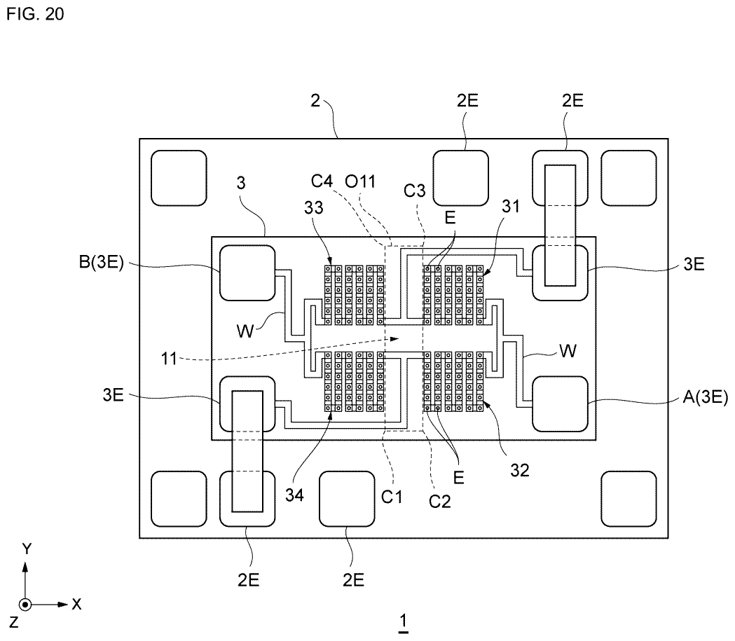

In the magnetic sensor device 1 of the present disclosure, as in the third example shown in FIG. 19, all the plurality of magnetic detection elements E may be disposed at the inside of the outline O11 in a plan view, or as in the fourth example shown in FIG. 20, all the plurality of magnetic detection elements E may be disposed at the outside of the outline O11 in a plan view. The magnetic sensor device 1 of the present disclosure has few restrictions on arrangement of the magnetic detection elements E, and has an excellent degree of freedom in design.

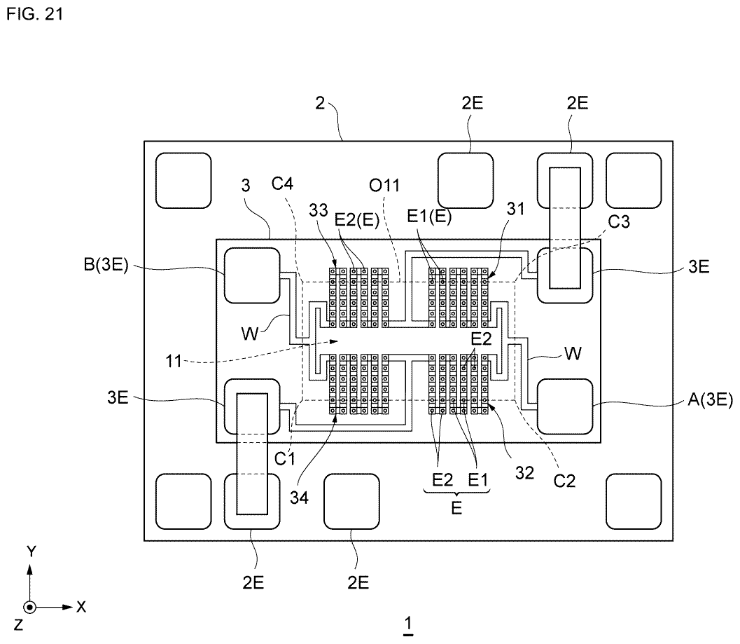

FIGS. 21 to 23 are plan views showing fifth to seventh examples in which a first magnetic detection element E1 may be disposed to overlap the outline O11 of the hole portion 11 other than the corners C1 to C4 and a second magnetic detection element E2 may be disposed not to overlap the outline O11 of the hole portion 11. Positions other than corners C1 to C4 that overlap the outline O11 of the hole portion 11 are slightly more likely to be influenced to the thermal stress than positions that do not overlap the outline O11, but the influence of the thermal stress is sufficiently small as compared to the positions that overlap the corners C1 to C4. In the fifth to seventh examples, each of the plurality of magnetic detection elements E may not overlap any of the corners C1 to C4 of the outline O11 of the hole portion 11 in a plan view. For that reason, the magnetic detection elements E (the first magnetic detection element E1 and the second magnetic detection element E2) are less likely to be influenced by the thermal stress from the sensor substrate 10.

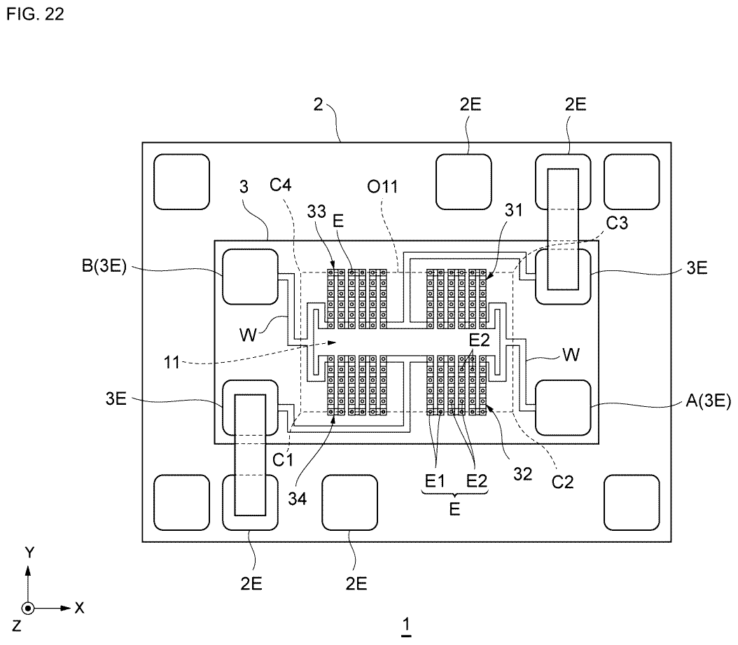

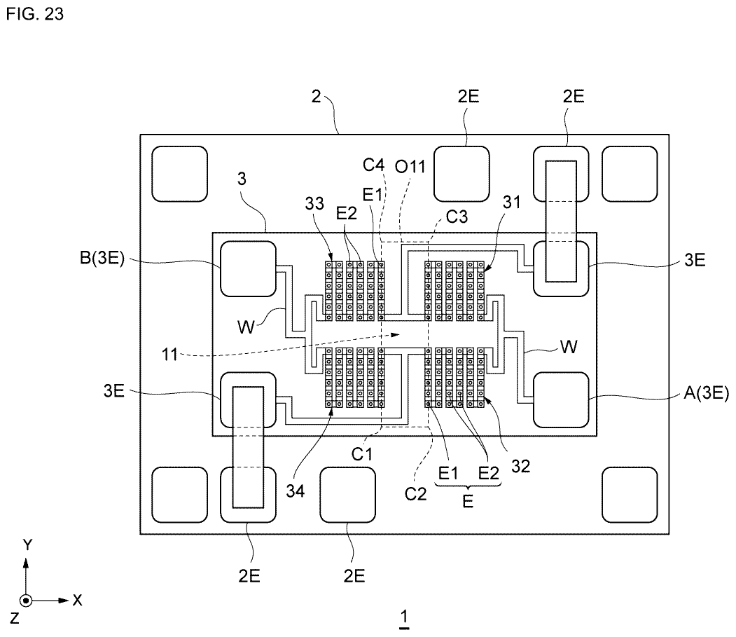

In the magnetic sensor device 1 of the present disclosure, as in the fifth example shown in FIG. 21, the second magnetic detection element E2 that may not overlap the outline O11 of the hole portion 11 may be disposed across the inside and the outside of the outline O11 in a plan view, as in the sixth example shown in FIG. 22, the entire second magnetic detection element E2 may be disposed at the inside of the outline O11 in a plan view, or as in the seventh example shown in FIG. 23, the entire second magnetic detection element E2 may be disposed at the outside of the outline in a plan view. The magnetic sensor device 1 of the present disclosure has few restrictions on the arrangement of the magnetic detection elements E, and has an excellent degree of freedom in design.

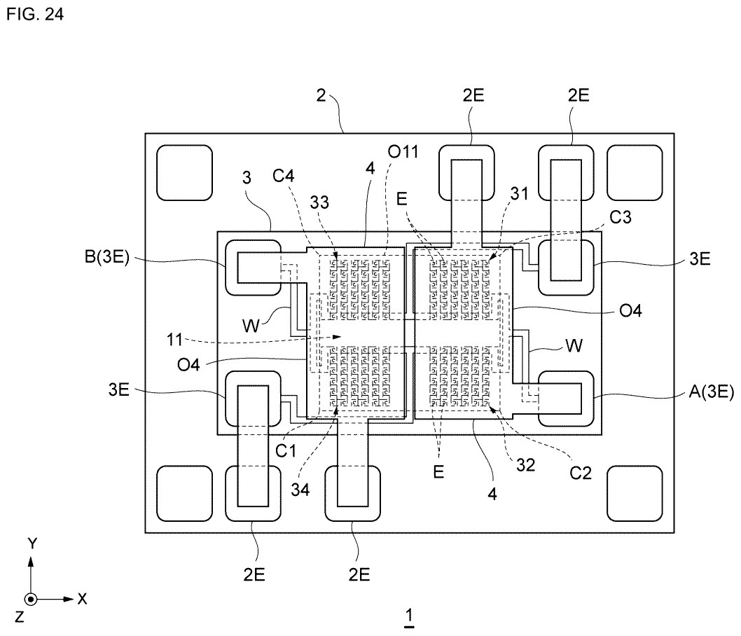

FIG. 24 is a plan view showing an eighth example in which the wiring layer 4 is added to the first example shown in FIG. 17 so that the magnetic detection elements E may be disposed at the inside of the outline O4 of the wiring layer 4. In the eighth example, similarly to the first example, each of the plurality of magnetic detection elements E may not overlap any of the corners C1 to C4 of the outline O11 of the hole portion 11 in a plan view. For that reason, the magnetic detection elements E are less likely to be influenced by the thermal stress from the sensor substrate 10. As described with reference to FIG. 15, adding the wiring layer 4 reduces the angular error at the inside of the outline O4 of the wiring layer 4. In the eighth example, it can be expected that the influence of the thermal stress will be even smaller than in the first example.

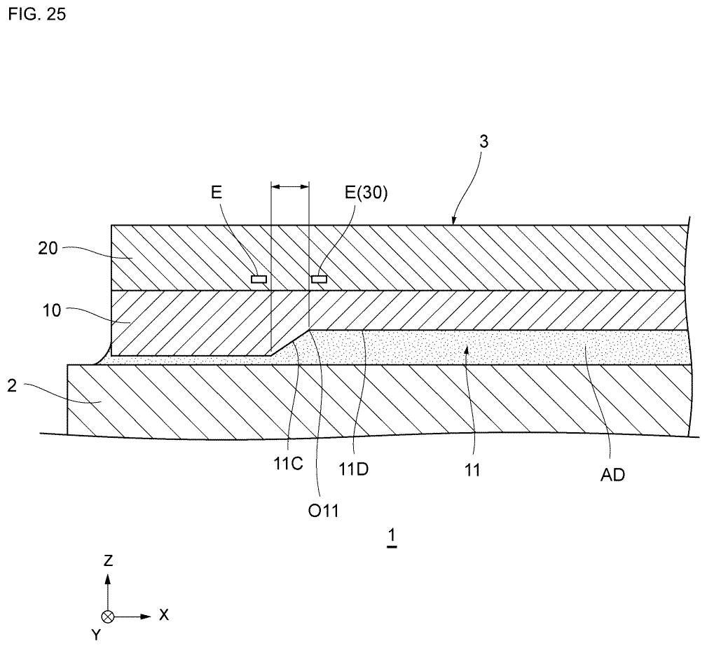

FIG. 25 is a cross-sectional view showing a ninth example in which the magnetic detection elements may be disposed not to overlap the inclined inner surface. As described with reference to FIG. 16, when there is the inner surface 11C inclined with respect to the plane-normal direction Z, there is a tendency that the position overlapping the inner surface 11C in a plan view is likely to be influenced by the thermal stress from the sensor substrate 10. In the ninth example, since each of the plurality of magnetic detection elements E does not overlap the inclined inner surface 11C, the magnetic detection elements E are less likely to be influenced by the thermal stress from the sensor substrate 10.

According to the magnetic sensor device 1 of the present disclosure configured as above, the hole portion 11 is formed in the sensor substrate 10, and thus even if the amount of application of the adhesive AD changes, the amount of the adhesive AD protruding from the first surface 10B of the sensor substrate 10 is less likely to change as compared to the case in which the hole portion 11 is not formed. The adhesive layer becomes thicker and the adhesive strength also improves. Accordingly, the sensor substrate 10 can be bonded to and appropriately fixed to the support substrate 2. In a plan view, the positions overlapping the corners C1 to C4 of the outline O11 of the hole portion 11 are likely to be influenced by the thermal stress, while each of the plurality of magnetic detection elements E does not overlap any of the corners C1 to C4, and thus it is less likely to be influenced by the thermal stress. It is possible to provide the magnetic sensor device 1 in which the output characteristics of the magnetic detection element arrays are stable.

When the sensor substrate 10 is fixed to the support substrate 2 using the adhesive AD, and the hole portion 11 is filled with the adhesive AD, the sensor substrate 10 can be appropriately fixed to the support substrate 2 using the adhesive AD.

Each of the plurality of magnetic detection elements E may be disposed not to overlap the outline O11 in a plan view. The positions other than corners C1 to C4 that overlap the outline of the hole portion 11 are not as strongly influenced as the positions that overlap corners C1 to C4, but they are slightly more likely to be influenced by the thermal stress than positions that do not overlap the outline O11. According to this aspect, since each of the plurality of magnetic detection elements E may not overlap the corners C1 to C4 and any of the outlines O11, it is less likely to be influenced by the thermal stress and the output characteristics are stabilized.

Some of the plurality of magnetic detection elements E may be disposed at the inside of the outline O11 in a plan view, and the remainder of the plurality of magnetic detection elements E may be disposed at the outside of the outline O11 in a plan view. All the plurality of magnetic detection elements E may be disposed at the inside of the outline O11 in a plan view. All the plurality of magnetic detection elements E may be disposed at the outside of the outline O11 in a plan view. The magnetic detection elements E can be disposed across the inside and the outside of the outline O11, the magnetic detection elements E can also be disposed only at the inside of the outline O11, or the magnetic detection elements E can also be disposed only at the outside of the outline O11. There are few restrictions on the arrangement of the magnetic detection elements E, and the degree of freedom in design is excellent.

Each of the plurality of magnetic detection elements E may be disposed at an interval of 1 μm or more from the outline O11 in a direction perpendicular to the plane-normal direction Z. When each of the plurality of magnetic detection elements E is located at least 1 μm away from the outline O11, it is less likely to be influenced by the thermal stress.

The hole portion 11 may be a bottomed hole recessed from the upper surface (first surface) 10B toward the lower surface (second surface) 10A, and the depth D of the bottomed hole may be less than or equal to half the thickness T of the sensor substrate 10 in the plane-normal direction. As the hole portion 11 may become deeper, a difference in thicknesses of the sensor substrate between the thickness at the hole portion 11 and the thickness at other portions may increase, and when the sensor substrate 10 expands or contracts due to a change in temperature, the magnetic detection elements E are likely to be influenced by the thermal stress. According to this aspect, since the difference may be less than or equal to half of the thickness T, the influence of the thermal stress is unlikely to become excessive.

The wiring layer 4 provided in a layer more distant from the support substrate 2 than the functional film 20 in the plane-normal direction Z may be further provided, and each of the plurality of magnetic detection elements E may be disposed at the inside of the outline O4 of the wiring layer 4 in a plan view. When the magnetic detection elements E are disposed at the inside of the outline O4 of the wiring layer 4, the magnetic detection elements E are less likely to be influenced by the thermal stress than the case in which the wiring layer 4 is not provided.

The hole portion 11 may have the inner surface 11C inclined with respect to the plane-normal direction Z, and each of the plurality of magnetic detection elements E may be disposed not to overlap the inner surface 11C in a plan view. The position overlapping the inclined inner surface 11C is likely to be influenced by the thermal stress.

The example embodiments described above are intended to facilitate understanding of the present invention, and are not intended to be interpreted as limiting the present invention. Each of the elements included in the example embodiments, as well as their arrangements, materials, conditions, shapes, sizes, and the like are not limited to those illustrated, and can be changed as appropriate. Further, it is possible to partially replace or combine the structures shown in different example embodiments.

What is claimed is:

1. A magnetic sensor device comprising:
a support substrate; and
a sensor substrate fixed to the support substrate, wherein
the sensor substrate includes a first surface that faces the support substrate, and a second surface that is located on an opposite side to the first surface and that is provided with a functional film including a plurality of magnetic detection elements,
a hole portion is formed in the first surface,
an outline of the hole portion includes at least one corner, and
each of the plurality of magnetic detection elements is disposed not to overlap any of the at least one corner in a plan view seen in a plane-normal direction from the second surface toward the first surface.

2. The magnetic sensor device according to claim 1, wherein
the sensor substrate is fixed to the support substrate by using an adhesive, and
the hole portion is filled with the adhesive.

3. The magnetic sensor device according to claim 1, wherein each of the plurality of magnetic detection elements is disposed not to overlap the outline in the plan view.

4. The magnetic sensor device according to claim 3, wherein
some of the plurality of magnetic detection elements are disposed at an inside of the outline in the plan view, and
the remainder of the plurality of magnetic detection elements are disposed at an outside of the outline in the plan view.

5. The magnetic sensor device according to claim 3, wherein all the plurality of magnetic detection elements are disposed at an inside of the outline in the plan view.

6. The magnetic sensor device according to claim 3, wherein all the plurality of magnetic detection elements are disposed at an outside of the outline in the plan view.

7. The magnetic sensor device according to claim 3, wherein each of the plurality of magnetic detection elements is disposed at an interval of 1 μm or more from the outline in a direction perpendicular to the plane-normal direction.

8. The magnetic sensor device according to claim 1, wherein the plurality of magnetic detection elements include at least one first magnetic detection element disposed to overlap the outline in the plan view.

9. The magnetic sensor device according to claim 8, wherein
the plurality of magnetic detection elements further include a plurality of second magnetic detection elements disposed not to overlap the outline in the plan view, and
some of the plurality of second magnetic detection elements are disposed at an inside of the outline in the plan view, and the remainder of the plurality of second magnetic detection elements are disposed at an outside of the outline in the plan view.

10. The magnetic sensor device according to claim 8, wherein
the plurality of magnetic detection elements further include at least one second magnetic detection element disposed not to overlap the outline in the plan view, and
all of the at least one second magnetic detection element are disposed at an inside of the outline in the plan view.

11. The magnetic sensor device according to claim 8, wherein
the plurality of magnetic detection elements further include at least one second magnetic detection element disposed not to overlap the outline in the plan view, and
all of the at least one second magnetic detection element are disposed at an outside of the outline in the plan view.

12. The magnetic sensor device according to claim 1, wherein the plurality of magnetic detection elements are disposed at intervals of 1 μm or more from all of the at least one corner in an in-plane direction perpendicular to the plane-normal direction.

13. The magnetic sensor device according to claim 1, wherein
the hole portion is a bottomed hole recessed from the first surface toward the second surface, and
a depth of the bottomed hole is less than or equal to half a thickness of the sensor substrate in the plane-normal direction.

14. The magnetic sensor device according to claim 1 further comprising a wiring layer provided in a layer more distant from the support substrate than the functional film in the plane-normal direction, wherein
each of the plurality of magnetic detection elements is disposed at an inside of the outline of the wiring layer in the plan view.

15. The magnetic sensor device according to claim 1, wherein
the hole portion includes an inner surface inclined with respect to the plane-normal direction, and
each of the plurality of magnetic detection elements is disposed not to overlap the inner surface in the plan view.

16. An angle sensor comprising the magnetic sensor device according to claim 1.

17. A magnetic compass comprising the magnetic sensor device according to claim 1.

18. A current sensor comprising the magnetic sensor device according to claim 1.

19. A camera module comprising an autofocus mechanism and/or an optical image stabilization mechanism including the magnetic sensor device according to claim 1.

20. A magnetic sensor device comprising:
a support substrate; and
a sensor substrate fixed to the support substrate, wherein
the sensor substrate includes a first surface facing the support substrate, and a second surface that is located on an opposite side to the first surface and that is provided with a functional film including a plurality of magnetic detection elements,
a hole portion that is a bottomed hole recessed from the first surface toward the second surface or a through hole penetrating from the first surface to the second surface is formed in the first surface, and
an outline of the hole portion is a circle not including a corner.
